(19) United States
(12) Patent Application Publication
(10) Pub. No.: US 2016/0013345 A1
(43) Pub. Date: Jan. 14, 2016

(54) PHOTOVOLTAIC MODULE ASSEMBLY

(71) Applicant: Valoe Oyj, Mikkeli (FI)

(72) Inventors: Henrikki Pantsar, Helsinki (FI); Ville Lampinen, Turku (FI); Timo Savikko, Espoo (FI); Jarko Nieminen, Lohja (FI); Tuukka Savisalo, Mikkeli (FI)

(21) Appl. No.: 14/773,080

(22) PCT Filed: Mar. 4, 2014
(86) PCT No.: PCT/FI2014/050161

§ 371 Date: Sep. 4, 2015

(30) Foreign Application Priority Data
Mar. 5, 2013 (FI) 20135213

(51) Int. Cl. H01L 31/05; H01L 31/048; H01L 31/049; H01L 31/0224

(52) U.S. Cl. CPC H01L 31/0504; H01L 31/022441; H01L 31/048; H01L 31/049

(57) ABSTRACT

A method and a system for assembling a photovoltaic module including at least one photovoltaic cell including electrical contacts on the same side of the cell, a back sheet, a sheet of encapsulant material configured to be assembled between the photovoltaic cell and the back sheet and conductive circuit elements between the back sheet and the sheet of encapsulant material. The method includes printing at least one layer of interconnecting paste to the electrical contacts of the photovoltaic cell.

### FIELD OF THE INVENTION

The invention relates to photovoltaic modules. More specifically, the invention relates to a method and a system for assembling a photovoltaic module.

### BACKGROUND OF THE INVENTION

Photovoltaic cells or solar cells are assembled together to form a photovoltaic module. Such modules are also known as solar modules or solar panels. The photovoltaic module is a large area optoelectronic device that converts the energy of light such as solar radiation directly into electricity by the photovoltaic effect.

Photovoltaic modules are commonly manufactured using crystalline silicon cells that are electrically connected in series using tabs and strings. These assemblies are encapsulated to protect the assembly from environment and also to provide safe electrical connections. The top side of the assembly is generally covered with glass and the backside with flexible polymer laminate, though glass can also be used for the back. This assembly method is difficult to fully automate and thus often involves large amounts of manual labour.

U.S. Pat. No. 5,972,732A describes a “monolithic module assembly”, a planar process that is better suited for automation. The process utilizes back contact photovoltaic cells wherein both emitter and collector contacts are on the same side of the photovoltaic cell.

A common method to apply interconnecting paste between the photovoltaic cell and the conductive back sheet is to print it to the conductive elements of the back sheet. The problem of this method is that the large area printer used for printing to the connecting pads of the back sheet cannot be positioned accurately over the whole back sheet, since the back sheet may comprise large manufacturing tolerances. The back sheet may be a large object, with surface dimensions of up to 1 m×2 m. Ensuring uniform paste and pressure distribution for the whole area is difficult, leading to uneven size and shape of the interconnecting paste across the whole printing area. Also the tooling, such as stencils or screens used to apply the interconnecting paste, are large and expensive. For the large stencil the thermal expansion may lead to significant misalignment of the circuits, contacts on the photovoltaic cells and the interconnecting paste. The shape of the interconnecting paste may result to a shape, where the top is much smaller and less defined than the bottom. As the paste is printed on the back sheet, the shape is not optimal for providing the connection. The contact resistance of the contact pad is significantly larger than on the conductive circuit element, thus the contact pad size on the cell is more critical. The contact resistance on the photovoltaic cell is more difficult to optimize than the contact resistance on the back sheet, therefore narrow paste on the photovoltaic cell may lead to increased contact resistance. After the lamination and the paste curing process poorly defined paste may lead to poor contact not offering enough contact surfaces. Excessive misalignment, caused by inaccuracies of the process or the placement or shape of the conductive circuit elements, may lead to short circuiting of the complete assembly.

### SUMMARY

The present invention discloses a method of assembling a monolithic, back contact photovoltaic module. The photovoltaic module comprises at least one photovoltaic cell comprising electrical contacts on the same side of the cell, a back sheet and a sheet of encapsulant material configured to be assembled between the photovoltaic cell, the back sheet and conductive circuit elements between the back sheet and the sheet of encapsulant material. The method comprises printing at least one layer of interconnecting paste to the electrical contacts of the photovoltaic cell.

In one embodiment the method comprises assembling the photovoltaic module onto a transparent front sheet, such a glass panel, wherein the photovoltaic module is fully assembled with the front sheet facing down. In one embodiment the method comprises printing the at least one layer of interconnecting paste so as to cause the paste to form bumps with a tapered shape so that the diameter of the bumps is largest at the level of the cell contacts. In one embodiment the method comprises inspecting the cell before printing, causing a defective cell to be rejected.

Another aspect of the invention discloses a system for assembling a photovoltaic module comprising at least one photovoltaic cell comprising electrical contacts on the same side of the cell, a back sheet, a sheet of encapsulant material configured to be assembled between the photovoltaic cell and the back sheet and conductive circuit elements between the back sheet and the sheet of encapsulant material. The system comprises a printer, a dispenser or other means configured to print at least one layer of interconnecting paste to the electrical contacts of the photovoltaic cell.

In one embodiment the system comprises means for assembling the photovoltaic module onto a transparent front sheet, wherein the photovoltaic module is fully assembled with the front sheet facing down. In one embodiment the system comprises the printer being configured to print the at least one layer of interconnecting paste so as to cause the paste to form bumps with a tapered shape so that the diameter of the bumps is largest at the level of the cell contacts. In one embodiment the system comprises the printer being configured to inspect the cell, causing a defective cell to be rejected.

The embodiments of the invention described hereinbefore may be used in any combination with each other. Several of the embodiments may be combined together to form a further embodiment of the invention. A method, an apparatus, a system or a computer program to which the invention is related may comprise at least one of the embodiments of the invention described hereinbefore. It is to be understood that any of the above embodiments or modifications can be applied singly or in combination to the respective aspects to which they refer, unless they are explicitly stated as excluding alternatives.

The present invention is an assembly process for a monolithic photovoltaic module in which the interconnecting paste is printed on the photovoltaic cell instead of the conductive circuit element. The paste can be printed on the cell in a way that the paste position and shape is very precisely controlled.

The present invention enables using smaller tolerances in the paste to the cell which enable the reduction of the size of the contact pads, reducing the area of the isolated pad, thus increasing the effective area of the cell. Further, the improved tolerances in the assembly process enable more accurate features in the electrical connections of the module. This leads to better area utilization and less electrical resistance in the module and to improved module efficiency. The improved accuracy of printing the interconnecting paste leads to better efficiency and enables the use of more contact points. This opens up possibilities for more efficient electrical circuit design.

Printing the paste on the cell contacts enables also the use of substantially smaller printer equipment than in the traditional approach where the paste is printed on the conductive circuit elements of the large-area back sheet. Further, printing on the cell enables printing a tapered shape interconnecting paste. As a result, the contact on the photovoltaic cell, where the contact resistance is higher, is wider and very well defined.

Printing on the cells provides higher accuracies and thus leads to higher yield and reduces the risk of short circuiting. The contact resistance of the contact pad is significantly larger than on the conductive circuit element. Therefore maximizing the contact area between the paste and the contact pad of the cell provides means for improving the module performance by reducing resistance between the contact pad and the paste. This can be realized by printing the paste on the cell. When printing on the conductive circuit elements instead of cells, the tapered shape of the paste leads to less contact area between the contact pad of the cell and the interconnection paste than the conductive circuit elements and the paste. Printing on the cells and the resulting accuracy improvement further enables more accurate features in the electrical connections of the module, resulting to smaller losses in the module and improved module efficiency.

The photovoltaic cell is manufactured often in a different geographical location than the assembly of the photovoltaic module. The interconnecting paste could oxidize during the transportation; therefore the paste should be applied during the assembly phase. The invention improves the assembly process and enables a step to differentiate the manufacturing process from the assembly process.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings:

FIG. 1 is a block diagram illustrating an exemplary embodiment,

FIG. 2 illustrates the device elements according to the invention, and

FIG. 3 illustrates one stage of an assembly method according to the invention.

### DETAILED DESCRIPTION OF THE INVENTION

Reference will now be made in detail to the exemplary embodiments of the present invention, examples of which are illustrated in the accompanying drawings.

The photovoltaic module according to the present invention is an assembly comprising several photovoltaic cells that are connected together to increase the amount of power when exposed to light. The assembly usually comprises laminating the components to form a flat and rigid structure. An example of the photovoltaic module is a large flat sandwich structure, comprising a back sheet, conductive circuit elements to which the cells are connected, an encapsulant layer in the form of a sheet of encapsulant material to produce adhesion, mechanical protection and electrical insulation between the layers, photovoltaic cells electrically connected and arranged to be an array, another layer of insulation, typically in the form of another sheet of encapsulant, and the transparent front sheet such as a glass plate. In one example the size of one photovoltaic cell is 156×156 mm, wherein the total number of such cells may be 30, 48, 60 or 72 in a single module.

According to the innovation a screen/stencil printer according to prior art may be used for printing on the photovoltaic cells. The printing may also mean inserting volumes of paste dispensed from a nozzle. The accuracy of commercially available solar cell printers enables printing alignment to the cell with very small tolerances and the screen/stencil technology enables accurate engineering of paste shape, size and position. The cells are inspected in the printer for faults, so a defective cell will not reach the assembly cell.

The assembly process may start either from the back sheet or from the transparent front sheet. In the following, the assembly process is explained starting from the back sheet. The back sheet is pre-fabricated, comprising one or more protective layers. Examples of such layers are a layer of polyvinylfluoride and a carrier film commonly made of polyethylene terephthalate, PET. The back sheet may comprise electrically conductive circuit elements that provide the interconnections between photovoltaic cells and a layer of surface protection onto a flat carrier. In one embodiment the electrically conductive circuit element may be arranged between the sheet of encapsulant material and the back sheet. The sheet of encapsulant material is positioned between the conductive circuit elements and the photovoltaic shell, said element providing connection between different photovoltaic cells. In one embodiment, the encapsulation sheet may comprise the conductive circuit elements.

The interconnecting paste is printed to the contact points of the photovoltaic cell. The paste contains metal particles, such as silver, forming after the curing process a solid conductor between the cell contacts, either front or back, and the conductive circuit elements on the back sheet. Instead of a curable paste, the interconnecting material may also be a solder paste. A sheet of encapsulant material is positioned on the back sheet, wherein the holes of the encapsulant sheet are positioned to align to the positions of the interconnecting paste. The encapsulant sheet is for example made of ethyl vinyl acetate (EVA). Back contact photovoltaic cells with the interconnecting paste on the contacts thereof are positioned onto the assembly aligning to the holes in the sheet of encapsulant material and the conductive elements.

Another sheet of encapsulant material is placed on top of the layer of photovoltaic cells and the protective top layer on the sheet of encapsulant material. The protective top layer is for example made of glass. The assembly according to this process may need to be turned around to be laminated with the protective top layer facing down. Before turning the assembly, it may require a preheating step to secure the assembled components.

Reference points are used to determine the assembly locations of the cells relative to the back sheet and in one embodiment the location of the interconnection paste bump to be printed on the cell. The reference points are detected for example by optical recognition means such as a camera and corresponding software in the assembly cell. Reference points may be the contact pads or the isolation area surrounding the contact pad. Fiducials are circuit pattern recognition marks that allow automated assembly equipment to accurately locate and place components on the back sheet. Fiducials may also be used to position the printing of the interconnection paste.

In addition, the method for printing the interconnection paste on the cells enables modification of the paste geometry prior to assembly. One particularly useful paste shape is tapered. The tapered shape results from the printing process and is advantageous, as it creates a larger contact area between the cell and the paste, which has a higher contact resistance. In the case of printing the interconnection paste on the conductive elements of the back sheet, the contact area is larger between the back sheet and the paste, and smaller between the paste and the cell. This results in increased contact resistance and reduces the performance of the module.

If a positional difference exists between the photovoltaic cell and the corresponding contact pad on the back sheet, it may be compensated to some degree by a larger hole and contact pad. On the other hand, the size of the contact pad may be reduced by more accurate positioning of the interconnecting paste.

In one embodiment the assembly is started from the protective top layer such as glass. The glass is placed in the desired position by detecting the locations of edges or corners. An encapsulant layer is placed on top of the glass. Photovoltaic cells with interconnection paste are then placed on the glass and encapsulant. The encapsulant, comprising holes for interconnections, conductive circuit elements and the back sheet are precisely placed on top of the cells, so that the paste creates the interconnection between the cells and the conductive circuit elements through the holes. When the assembled module is already the protective top cover facing down, there is no need to flip the semi-assembled module before entering the final lamination step.

Heat may be applied to fix all components in place. The completed assembly is then moved to the laminating machine, where air is removed from the assembly and heat is applied, allowing the encapsulant material to flow and fill all gaps in the assembly. The heat applied in the laminating process cures the interconnection material. Alternatively a separate process may be used to ensure good electrical contact between the contacts on the photovoltaic cells and the conductors on the back sheet. In one embodiment such process may be soldering.

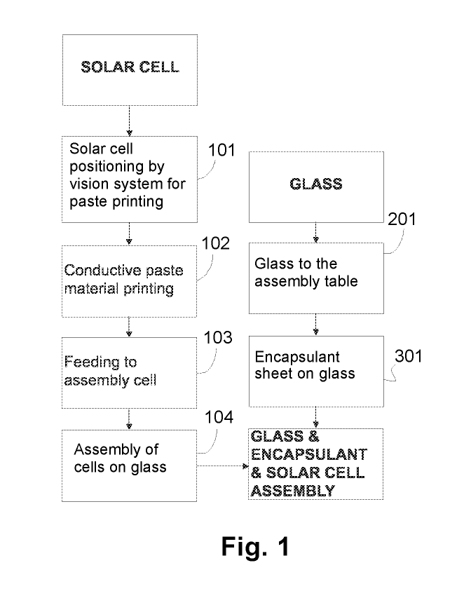

The flow chart of FIG. 1 illustrates an assembly method where the assembly is carried out by stacking the layers of the photovoltaic module on a glass cover sheet. For preparing a solar cell for the actual assembly, it is first positioned appropriately for paste printing by a vision system in step 101. Next, in step 102, conductive paste is printed on the contacts on the back side of the cell. The cell with the paste is then fed to the actual assembly cell in step 103 and photovoltaic cells are assembled on the glass in step 104. A sheet of encapsulant material is brought in step 301 onto the glass cover sheet, which is placed on an assembly table in step 201. In step 301, the prepared cells with the paste thereon are assembled in an array on the sheet of encapsulant material lying on the glass cover sheet so as to form a sub-assembly comprising the glass cover sheet, the sheet of encapsulant material, and the array of solar cells. Next, the other sheet of encapsulant material, the conductive circuit elements and the back sheet are added to this sub-assembly (not illustrated in the figure) to form an entire photovoltaic module. Other methods for assembling the module are also possible, for example the assembly does not need to be simultaneous. Different orders of assembling the module are also possible.

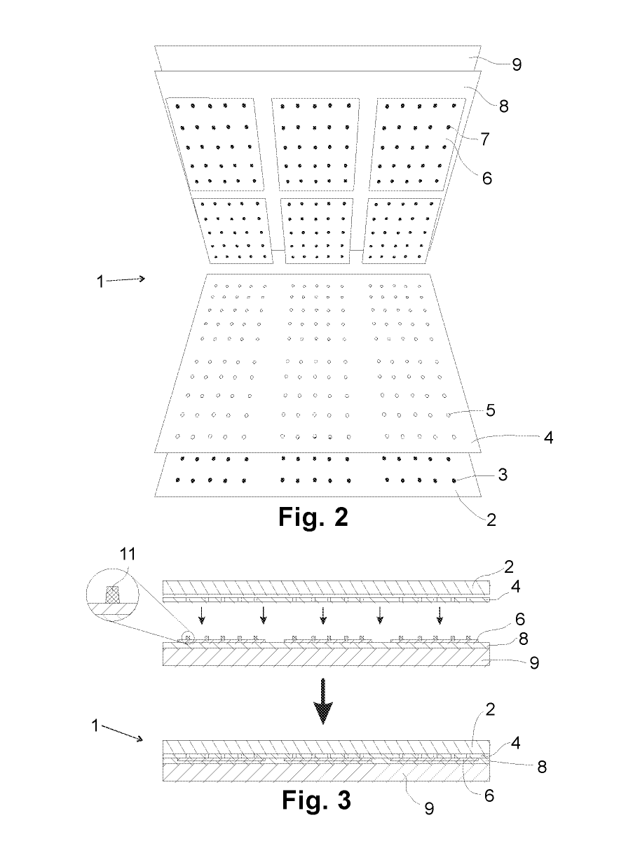

The exploded view of FIG. 2 shows the five essential layers of the photovoltaic module 1: a back sheet 2 having contact pads 3 thereon; a first sheet of encapsulant material 4 having interconnecting holes 5 therein; an array of photovoltaic cells 6, each having an array of contacts 7 on the back side of the cell; a second sheet of encapsulant material 8; and a transparent front sheet 9 made of e.g. glass. The exploded view illustrates the importance of accurate positioning of the back sheet, the first sheet of encapsulant, and the array of the photovoltaic cells: the contacts of the cells, the holes in the first sheet of encapsulant material, and the contact pads of the back sheet must coincide in order to form the appropriate electrical connections.

FIG. 3 illustrates the assembly of the photovoltaic module 1. In the example of FIG. 3, the parts of the photovoltaic module are the same as those in FIG. 2. The layer stack of the photovoltaic module 1 is assembled upside down on the front sheet 9. As an essential difference to the prior art assembly methods, bumps of conductive paste 11 are printed directly on the cell contacts instead of the corresponding locations on the back sheet contact pads. As shown in the partial magnification, the bumps 11 have a tapered form, wherein the width of the bump is at its maximum at the level of the cell contact, and narrows as a function of distance from this level. The maximum width at the cell contact minimizes the junction resistance between the cell contact and the encapsulant material. On the other hand, the narrower bumb top facilitates the positioning of the cells with respect to the contact pads of the back sheet and the holes in the first sheet of encapsulant material.

When the second sheet of encapsulant material 8 and the array of photovoltaic cells have been stacked on the front sheet, the first sheet of encapsulant 4 is brought onto the stack.

In FIGS. 2 and 3, for the sake of clarity of the drawings, the exemplary photovoltaic module comprises only 6 photovoltaic cells. However, in practice, the photovoltaic module may comprise any appropriate number of photovoltaic cells. Typically, a photovoltaic module comprises some tens of photovoltaic cells.

Embodiments of the present invention may be implemented in software, hardware, application logic or a combination of software, hardware and application logic. In an example embodiment, the application logic, software or instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer. A computer-readable medium may comprise a computer-readable storage medium that may be any media or means that can contain or store the instructions for use by or in connection with an instruction execution system, apparatus, or device, such as a computer. The exemplary embodiments can store information relating to various processes described herein. This information can be stored in one or more memories, such as a hard disk, optical disk, magneto-optical disk, RAM, and the like. One or more databases can store the information used to implement the exemplary embodiments of the present inventions. The databases can be organized using data structures (e.g., records, tables, arrays, fields, graphs, trees, lists, and the like) included in one or more memories or storage devices listed herein. The processes described with respect to the exemplary embodiments can include appropriate data structures for storing data collected and/or generated by the processes of the devices and subsystems of the exemplary embodiments in one or more databases.

All or a portion of the exemplary embodiments can be conveniently implemented using one or more general purpose processors, microprocessors, digital signal processors, micro-controllers, and the like, programmed according to the teachings of the exemplary embodiments of the present inventions, as will be appreciated by those skilled in the computer and/or software art(s). Appropriate software can be readily prepared by programmers of ordinary skill based on the teachings of the exemplary embodiments, as will be appreciated by those skilled in the software art. In addition, the exemplary embodiments can be implemented by the preparation of application-specific integrated circuits or by interconnecting an appropriate network of conventional component circuits, as will be appreciated by those skilled in the electrical art(s). Thus, the exemplary embodiments are not limited to any specific combination of hardware and/or software.

If desired, the different functions discussed herein may be performed in a different order and/or concurrently with each other.

Furthermore, if desired, one or more of the above-described functions may be optional or may be combined. Although various aspects of the invention are set out in the independent claims, other aspects of the invention comprise other combinations of features from the described embodiments and/or the dependent claims with the features of the independent claims, and not solely the combinations explicitly set out in the claims.

It is obvious to a person skilled in the art that with the advancement of technology, the basic idea of the invention may be implemented in various ways. The invention and its embodiments are thus not limited to the examples described above; instead they may vary within the scope of the claims.

1. A method of assembling a photovoltaic module, the photovoltaic module comprising:
at least one photovoltaic cell comprising electrical contacts on the same side of the at least one photovoltaic cell;
a back sheet;
a sheet of encapsulant material configured to be assembled between the at least one photovoltaic cell and the back sheet; and
conductive circuit elements between the back sheet and the sheet of encapsulant material;
the method comprising printing at least one layer of interconnecting paste to the electrical contacts of the at least one photovoltaic cell.

2. The method according to claim 1, further comprising assembling the photovoltaic module on a transparent front sheet, wherein the photovoltaic module is assembled with the transparent front sheet facing down.

3. The method according to claim 1, further comprising printing the at least one layer of interconnecting paste cause the interconnecting paste to form bumps with a tapered shape.

4. The method according to claim 1, further comprising inspecting the at least one photovoltaic cell before printing, causing a defective cell to be rejected.

5. A system for assembling a photovoltaic module, the photovoltaic module comprising: at least one photovoltaic cell comprising electrical contacts on the same side of the at least one photovoltaic cell;
a back sheet;
a sheet of encapsulant material configured to be assembled between the at least one photovoltaic cell and the back sheet; and
conductive circuit elements between a back sheet and the a sheet of encapsulant material; the system comprising:
a printer configured to print at least one layer of interconnecting paste to the electrical contacts of the at least one photovoltaic cell.

6. The system according to claim 5, further comprising means for assembling the photovoltaic module on a transparent front sheet, wherein the photovoltaic module is assembled with the transparent front sheet facing down.

7. The system according to claim 5, wherein the printer is configured to print the at least one layer of interconnecting paste so as to cause the interconnecting paste to form bumps with a tapered shape.

8. The system according to claim 5, wherein the printer is configured to inspect the at least one photovoltaic cell, causing a defective cell to be rejected.

9. The method according to claim 1, wherein the method further comprises determining locations of the conductive circuit elements relative to the back sheet using a plurality of reference points.

10. The method according to claim 1, wherein the sheet of encapsulant material comprises ethyl vinyl acetate (EVA).

11. The method according to claim 3, further comprising modifying geometry of the at least one layer of interconnecting paste.

12. The method according to claim 3, wherein the bumps comprise a maximum width at a contact point of the electrical contacts of the at least one photovoltaic cell.

13. The method according to claim 12, wherein a width of the bumps narrows as a function of a distance away from the contact point.

14. The method according to claim 1, wherein the electrical contacts are sized to be larger than the back sheet and smaller than the at least one photovoltaic cell.

15. The system according to claim 5, wherein the printer is further configured to determine locations of the conductive circuit elements relative to the back sheet using a plurality of reference points.

16. The system according to claim 5, wherein the sheet of encapsulant material comprises ethyl vinyl acetate (EVA).

17. The system according to claim 7, wherein the printer is further configured to modify geometry of the at least one layer of interconnecting paste.

18. The system according to claim 7, wherein the bumps comprise a maximum width at a contact point of the electrical contacts of the at least one photovoltaic cell.

19. The system according to claim 18, wherein a width of the bumps narrows as a function of a distance away from the contact point.

20. The system according to claim 5, wherein the electrical contacts are sized to be larger than the back sheet and smaller than the at least one photovoltaic cell.
